(19) United States
(12) Patent Application Publication
(10) Pub. No.: US 2007/0149001 A1
(43) Pub. Date: Jun. 28, 2007

(54) Flexible circuit

(76) Inventor: Harshad K. Uka, Irvine, CA (US)

Correspondence Address: STETINA BRUNDA GARRED & BRUCKER, 75 ENTERPRISE, SUITE 250, ALISO VIEJO, CA, 92656, US

(21) Appl. No.: 11/316,473

(22) Filed: Dec. 22, 2005

(51) Int. Cl. H05K 1/00; H01B 13/00; C23F 1/00; C23C 26/00; H05K 3/00; B05D 5/12

(52) U.S. Cl. 439/67; 216/13; 216/90; 216/41; 427/96.1; 427/98.6; 427/99.5; 427/97.8; 427/96.9

(57) ABSTRACT

A flexible circuit and a method of fabricating the flexible circuit is provided wherein adhesive is flowed into the interstices of a fabric. The adhesive is then cured to a “B” stage and a conductive foil is bonded to the adhesive on one or both sides of the fabric. Thereafter, the adhesive may be fully cured. A conductive pattern may then be etched into the conductive foil via print and etch techniques. The conductive pattern may be protected with a cover layer. For example, the cover layer may be a base layer with adhesive flowed in its pores and fully cured. The adhesive may be effectively formulated to withstand stresses between the adhesive and the conductive pattern such that bending and flexing the flexible circuit or subjecting the flexible circuit to thermal stresses does not delaminate the bond between the adhesive and the conductive pattern. The adhesive resists delamination from the fabric because the adhesive has been flowed into the fabric's interstices and cured.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

The present invention relates to flexible circuits.

Flexible circuits are utilized in many different applications. A common application is in printed wiring harnesses and the like. For example, a printer may have first and second components electrically connected to each other which are required to have freedom of movement with respect to each other. The components may be electrically connected to each other via the printed wiring harness or interconnect. In particular, the flexible circuit may have a first set of conductive pads at a first distal end of the flexible circuit. The first set of conductive pads may be electrically connected to the first component. Also, the flexible circuit may have a second set of conductive pads at a second distal end thereof which are electrically connected to the second component and the first set of conductive pads. In this manner, the first and second components have freedom of movement with respect to each other while maintaining electrical connectivity.

Prior art flexible circuits comprise a base film with a conductive pattern bonded to one or both sides of the base film. The conductive pattern is bonded to the base film via an intermediate adhesive because the conductive pattern cannot be directly bonded to the base film. For example, as shown in FIG. 2A, firstly, a manufacturer produces a continuous non reinforced flexible film. The base film may be KAPTON sold by Du Pont. Secondly, an adhesive film is deposited over the continuous non reinforced flexible film. Thirdly, the adhesive is cured to a B stage. Fourth, a conductive foil is bonded to the adhesive cured to the B stage. Fifth, the adhesive is fully cured. Sixth, a mask is laid down on the conductive foil in a conductive pattern configuration. Seventh, the film laminate is submersed in an etching solution. Eighth, the mask is removed. Ninth, the conductive pattern is coated with a cover layer. Unfortunately, adhesives that bond well to the base film does not bond well to copper (i.e., conductive pattern), and conversely, adhesives that bond well to copper (i.e., conductive pattern) does not bond well to the base film. Accordingly, as the first and second components rotate and translate with respect to each other and/or the flexible circuit is subjected to thermal stresses, the film tends to delaminate from the adhesive or the conductive pattern tends to delaminate from the adhesive depending on whether the selected adhesive bonds better with the base film or the conductive pattern material.

Another problem with prior art flexible circuits relate to plated through holes. Plated through holes electrically connect a first conductive pattern on a first side of the flexible circuit to a second conductive pattern on a second side of the flexible circuit. Initially, a conductive pad of the first conductive pattern is vertically aligned to a conductive pad of the second conductive pattern. A single hole is formed through the vertically aligned conductive pads of the first and second conductive patterns. The hole may be plated with a conductive material to electrically connect the vertically aligned conductive pads of the first and second conductive patterns. Unfortunately, the conductive material that bonds well to adhesive does not bond well with the base film. Accordingly, as the flexible circuit is subjected to thermal stresses or bent and twisted, the base film tends to delaminate from the plating material. This failure typically results from z axis expansion and is referred to as plated through hole (PTH) failure.

Another problem with prior art flexible circuits relate to pin holes in base films which can potentially short circuit electrical circuits formed on the base films.

Furthermore, the process of fabricating prior art flexible circuits prevents flexible circuits from automatic optical inspection (AOI) because the process of fabricating prior art flexible circuits subjects the prior art flexible circuits to high pressures and temperatures deforming the flexible circuits and introducing residual stresses into the flexible circuit such that the flexible circuit does not lay flat for automatic optical inspection and is not dimensionally stable (i.e., expands and contracts). Moreover, prior art flexible circuits may not be optically scanable because the base film of the flexible circuit may be substantially the same color (i.e., no contrast) as the conductive pattern thereby making it difficult for the optical system to inspect the flexible circuit.

Accordingly, there is a need in the art for an improved flexible circuit.

### BRIEF SUMMARY

The present invention addresses the needs discussed above as well as other needs discussed herein and known in the art. A method of fabricating a flexible circuit may include the steps of flowing adhesive into a fabric, curing the adhesive to a “B” stage, bonding a conductive film (e.g., conductive plane) on the adhesive, fully curing the adhesive while maintaining the adhesive's flexibility, and laying the conductive pattern on the adhesive via a print and etch process. Alternatively, the method of fabricating the flexible circuit may include the steps of flowing adhesive into a fabric, fully curing the adhesive while maintaining the adhesive's flexibility, and depositing the conductive pattern directly onto the fully cured adhesive.

The references to first, second, third, etc. steps in this disclosure are not for the purpose of limiting this disclosure. Rather, the references are merely for the purpose of identifying the steps of the method of fabricating the flexible circuit without any particular order unless indicated.

In the flowing the adhesive into the fabric step, the adhesive may be provided as an adhesive bath. In particular, a container with an open top may be provided. The container may have melted adhesive therein with the open top sufficiently large such that the fabric may be submersed in the adhesive bath and removed therefrom. The adhesive may be specially formulated to adhere better to the conductive pattern than the fabric. Nonetheless, after curing, the adhesive is attached to the fabric and does not delaminate from the fabric because the adhesive is flowed into the fabric and fully cured. To accomplish the step of flowing adhesive into the fabric, the fabric may be submersed into melted adhesive for an effective amount of time such that the adhesive is flowed in between the interstices of the fabric.

In the curing the adhesive to the “B” stage step, the adhesive soaked into the fabric may be dried and heated with a hot air dryer. In particular, the adhesive may be subjected to hot dry air via the hot air dryer until the adhesive is partially cured and dry to the touch. Alternatively, the adhesive may be cured via other curing methods. By way of example and not limitation, heating methods such as infrared radiation curing and non heating methods such as UV curing. Thereafter, the conductive film may be bonded to the adhesive in the bonding step prior to the adhesive being fully cured in the fully curing step.

In the laying down the conductive pattern on the adhesive step, a conductive foil may be bonded to the adhesive on one side or both sides of the fabric. The fabric with adhesive and a conductive foil bonded to the adhesive may be referred to as the laminate. A mask may be laid over the conductive foil in the configuration of the conductive pattern. The laminate with the mask may then be soaked in a suitable etching solution which dissolves the conductive foil except where the mask is laid over the conductive foil. After the etching solution has dissolved the conductive foil, the mask is removed, and the conductive pattern is exposed. The conductive pattern may then be protected with an insulating cover layer.

The adhesive used in the process may be effectively formulated to bond better with the conductive foil compared to the fabric. Nonetheless, the adhesive is effectively engaged to the fabric because the adhesive has been flowed into the interstices of the fabric and cured. Also, the adhesive does not delaminate from the conductive pattern because the adhesive bonds well to the conductive pattern material. After the adhesive is fully cured and the conductive foil bonded to the adhesive, the laminate remains sufficiently flexible to be used as a flex circuit as opposed to a rigid printed wiring board.

The flexible circuit of the present invention is dimensionally stable because the adhesive is flowed into the interstices of the fabric or pores of a base layer then cured. In essence, the adhesive and the fabric expand and contract due to thermal stresses at the same rate such that the interface between the adhesive and the base layer do not delaminate from each other. In contrast, in the prior art, the adhesive is merely adhered to the base layer. As such, the adhesive expands and contracts at a different rate compared to the base layer upon heating and cooling. The reason is that the adhesive and the base layer have different coefficients of thermal expansion. The different rates of expansion and contraction cause the adhesive to delaminate from the base layer at the interface thereof. Fortunately, in the present invention, the adhesive is flowed into pores or interstices of the base layer then fully cured. As such, the base layer and the adhesive expands and contracts at the same rate at the interface thereof thereby resisting delamination.

In an aspect of the flexible circuit, a base layer fabricated from liquid crystal polymers are weak mechanically. Fortunately, flowing adhesive (e.g., liquid crystal polymer based adhesive) into a liquid crystal polymer mesh strengthens the liquid crystal polymer base layer to create a dimensionally stable and stronger base layer.

In an aspect of the flexible circuit discussed herein, the same is more robust, rugged and durable compared to prior art flexible circuits. For example, the flexible circuit is more abrasion resistant compared to prior art flexible circuits in that non reinforced film (i.e, prior art base layers) is subject to more degradation due to abrasion resulting from flex motion.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a top view of a flexible circuit;

FIG. 2 is a flowchart of a method of fabricating the flexible circuit of FIG. 1;

FIG. 2A is a flowchart of a prior art process of fabricating a prior art flexible circuit;

FIG. 3 is an illustration of a first step and a second step in the method of fabricating the flexible circuit of FIG. 1;

FIG. 4 is an illustration of a third step in the method of fabricating the flexible circuit of FIG. 1;

FIG. 5 is a top view of a mask having a configuration of a conductive pattern illustrated in FIG. 1;

FIG. 6 is a cross sectional view of a plated through hole of the flexible circuit shown in FIG. 1;

FIG. 7 is an enlarged view of FIG. 6 illustrating the fabric with frayed ends about the inner surface of the through hole with plating conductive material flowed between the frayed ends;

FIG. 8 is an alternative method of bonding the conductive foil to the adhesive;

FIG. 9 is a pictorial illustration of an optical scanner checking whether the flexible circuit's dimensions are within tolerance; and

FIG. 10 is an exploded view of two flexible circuits stacked upon each other with a cover layer covering the top layer.

### DETAILED DESCRIPTION

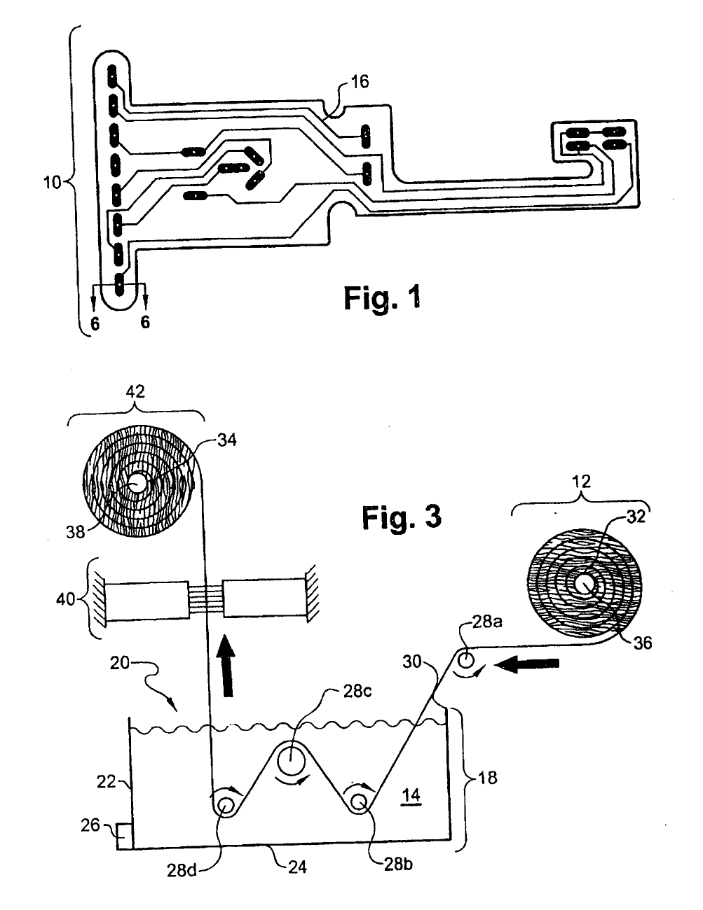

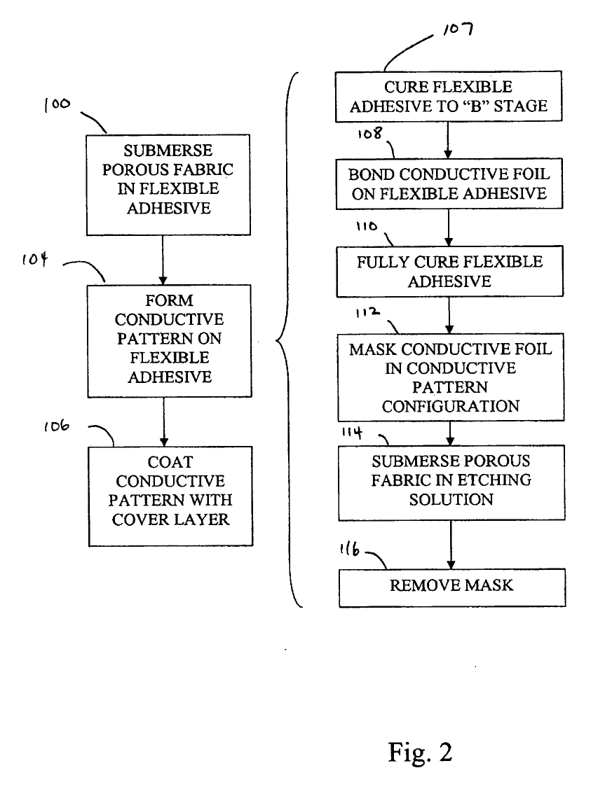

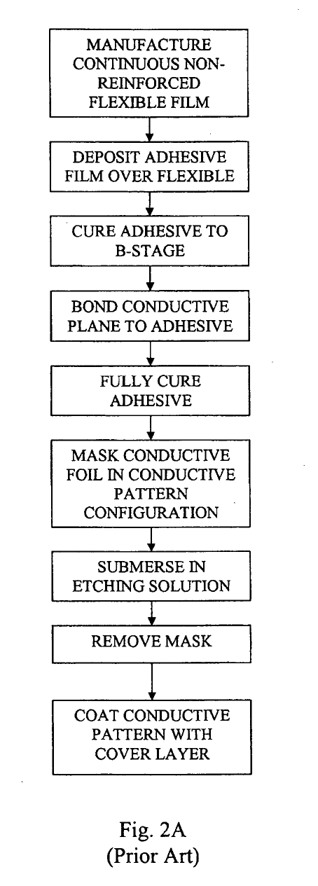

Referring now to FIGS. 1-3, a flexible circuit 10 is shown fabricated by submersing (step 100) a fabric 12 in an adhesive 14, forming (step 104) a conductive pattern 16 on the adhesive 14 of one side of the fabric 12, and coating (step 106) the conductive pattern 16 with a cover layer to protect the conductive pattern 16. The step of submersing 100 the fabric 12 in the adhesive 14 permits the adhesive 14 to flow through the fabric's interstices such that bending or flexing the flexible circuit 10 and/or the application of thermal stresses does not delaminate the adhesive 14 from the fabric 12. This step is different from the prior art process discussed in relation to FIG. 2A. In FIG. 2A, the adhesive is adhered to the exterior surface of the base film, whereas, the adhesive 14 discussed in relation to the present invention is disposed between the interstices of the fabric 12. Additionally, the adhesive 14 may be effectively formulated so as to adhere to the conductive pattern 16 such that bending and flexing the flexible circuit 10 and/or the application of thermal stresses does not delaminate the conductive pattern 16 from the adhesive 14.

The step of submersing 100 the fabric 12 in the adhesive 14 is illustrated in FIG. 3. The submersing step may be referred to as converting. The machine used to submerse the fabric in the adhesive may be referred to as a converter. The adhesive 14 may be provided in a container 18. The container 18 may have an open top 20 with four sides 22 and a bottom 24. The container 18 may hold adhesive 14 in the liquid state as well as the solid state (e.g., plurality of beads, etc.). The container 18 may be in heat communication with a heater 26 to heat the contents of the container 18. The heater 26 may be operative to inject a sufficient amount of heat into the container 18 so as to melt the adhesive 14 in the container from the solid state to the liquid state.

The container 18 may also include a plurality of rollers 28a-d through which the fabric 12 may be fed to submerse the fabric 12 within the adhesive 14. In particular, a first roller 28a may be positioned above an inlet lip 30 of the container 18. The first roller 28a guides the fabric 12 from a first tube 32 to roller 28b. The fabric 12 may be wrapped under the second roller 28b which is positioned near the bottom 24 of the container 18. The fabric 12 may also be wrapped around the third roller 28c and the fourth roller 28d which are positioned at different depths within the container. The second, third and fourth rollers 28b, c, d may be positioned within container 18 such that the fabric 12 when wrapped thereabout may form a W shaped configuration, as shown in FIG. 3. The fabric 12 may be wrapped under the second and fourth rollers 28b, d to ensure that the fabric 12 is submersed within the adhesive 14 even if the adhesive level within the container 18 is low.

As shown in FIG. 3, the rollers 28a-d may be rotated to feed the fabric 12 through the container 18 and onto the second tube 34. The rotational speed of the rollers 28a-d may be controlled to submerse (step 100) the fabric 12 in the adhesive 14 for an effective amount of time such that the adhesive 14 is flowed into the interstices of the fabric 12. For example, the rotational speed of the rollers 28a-d may be decreased to submerse the fabric 12 in the adhesive 14 for a longer period time, or the rotational speed of the rollers 28a-d may be increased to submerse the fabric 12 in the adhesive 14 for a shorter period of time. The rotational speed of the rollers 28a-d may be decreased (i.e., linear speed of fabric 12 decreased) if the adhesive 14 is not flowed into the interstices of the fabric 12. The flowing of the adhesive 14 into the fabric's interstices affects the ability of the adhesive 14 to engage the fabric 12 and not delaminate from the fabric 12 when the flexible circuit 10 is being flexed and bent or subjected to thermal stresses.

The fabric 12 may be provided as a roll of fabric 12 wrapped around the first tube 32 which allows the fabric 12 to be linearly unwound and submersed (step 100) into the adhesive 14 such that small portions of the fabric 12 may be sequentially submersed (step 100) in the adhesive 14. In particular, the beginning of the roll of fabric 12 may be fed through the rollers 28a-d, submersed (step 100) in the adhesive 14, removed from the adhesive 14 and attached to the second tube 34. The entire linear length of the fabric 12 may be sequentially submersed in the adhesive 14 until the entire roll of fabric 12 has been submersed in the adhesive 14 and the adhesive 14 has flowed into the fabric's interstices. More particularly, the roll of fabric 12 may be provided on the first tube 32. The fabric 12 is wrapped or rolled around the first tube 32 which may be mounted to a first spindle 36. A first distal end (i.e., fabric's beginning) of the fabric 12 may be fed through the plurality of rollers 28a-d and engaged to the second tube 34 mounted to a second spindle 38. The second spindle 38 may be rotated to wrap the fabric 12 onto the second tube 34. The rotational speeds of the rollers 28a-d and the spindles 36, 38 may be regulated to apply a controlled amount of tension on the fabric 12 and to control the amount of time the fabric 12 is submersed in the adhesive 14.

The container 18 may be filled with adhesive 14 in a solid or liquid form. If the adhesive 14 is provided in the solid form, then the container's heaters 26 may heat the container 18 to melt the adhesive 14. After the adhesive 14 is melted, the fabric 12 may be linearly pulled through the melted adhesive 14 to flow the adhesive 14 into the interstices of the entire roll of fabric 12. If the adhesive 14 is not effectively flowed into the interstices of the fabric 12, then the rotational speed of the plurality of rollers 28a-d may be decreased to increase the amount of time that the fabric 12 is submersed (step 100) within the adhesive 14.

The conductive pattern 16 of the flexible circuit 10 may be formed (step 104) on the adhesive 14 of one or both sides of the fabric 12 via a subtractive process or an additive process. By way of example and not limitation, the flexible may be formed on the adhesive via the subtractive process shown in FIG. 2. In particular, after the fabric is submersed into the adhesive, the adhesive 14 flowed into the fabric's interstices may be cured (step 107) to the “B” stage. The adhesive 14 may be cured to a “B” stage via air heaters/dryers 40, as shown in step 107 in FIG. 2 and FIG. 3. An adhesive cured to the “B” stage is dry to the touch but not fully cured. More particularly, the heater/dryer 40 may be placed inline with the container 18 and rollers 28a-d such that the adhesive 14 soaked into the fabric 12 may be immediately cured (step 107) to the “B” stage once the fabric 12 is removed from the container 18. For example, the heater/dryer 40 may be positioned above the container 18, and more particularly, may be positioned over the fourth roller 28d. The heater/dryer may be placed on opposing sides of the fabric 12 so as to apply dry heated air over the adhesive 14 of both sides of the fabric 12. More particularly, the adhesive 14 soaked in the fabric 12 is subjected to the dry heated air until the adhesive 14 is cured (step 107) to the “B” stage. To this end, the fabric's linear speed through which it travels through the heater/dryer 40 may be increased or decreased such that less or more dry heated air is applied to the adhesive 14 and the adhesive 14 is cured to the “B” stage.

The heater/dryer 40 may blow dry heated air against one, or preferably, both sides (see FIG. 3) of the fabric 12 to cure (step 107) the adhesive 14 that has been flowed into the fabric's interstices to the “B” stage. Although only one heater/dryer 40 is shown in FIG. 3, it is also contemplated that a plurality of heaters/dryers 40 be placed in a row to cure (step 107) the adhesive to the “B” stage. The additional heaters/dryers 40 may be necessary to increase the length of time that the adhesive 14 is subjected to the dry heated air to cure (step 107) the adhesive to the “B” stage. Alternatively, the adhesive 14 may be subjected to dry heated air for a longer duration of time by slowing down the linear speed of the fabric 12 through the heater/dryer 40. This may be accomplished by decreasing the rotational speed of the rollers 28a-d and spindles 36, 38. After the adhesive 14 flowed into the fabric's interstices is cured (step 107) to the “B” stage, the fabric 42 (see FIG. 3) with adhesive cured to the “B” stage may be wrapped around the second tube 34 for subsequent processing and for ease of transporting the fabric 12 throughout the fabricating plant. As used herein, the “fabric 42” refers to fabric 12 with adhesive flowed between the fabric's interstices and cured to the “B” stage.

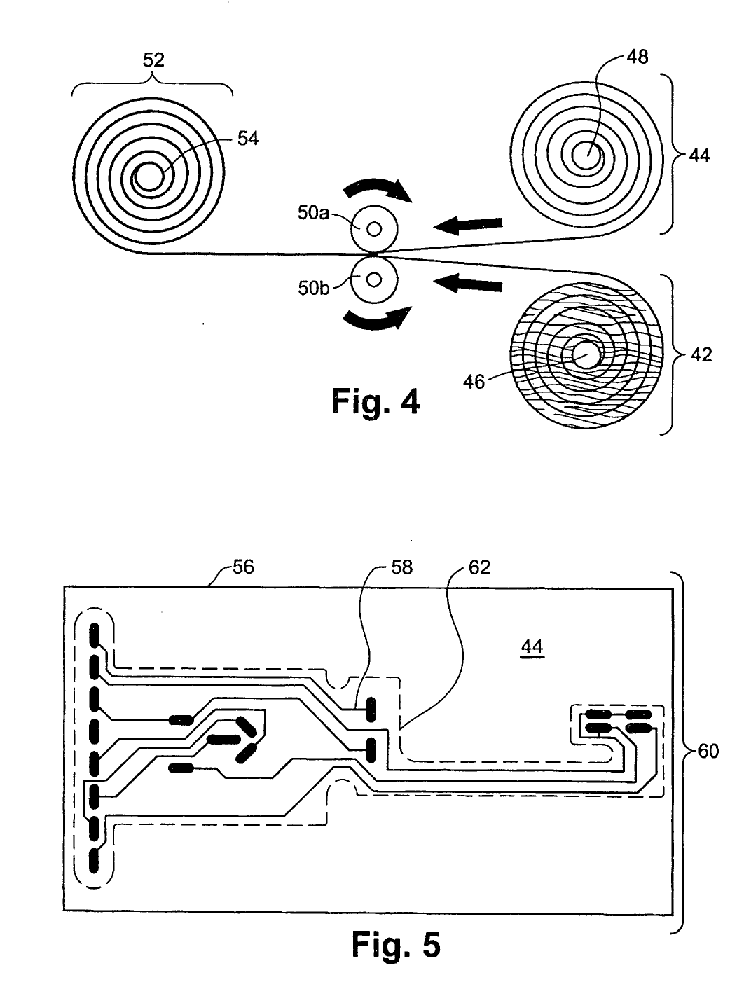

After the adhesive is cured to the “B” stage, a conductive foil 44 may be bonded/laminated (step 108) onto the adhesive 14 flowed into the fabric's interstices. For example, as shown in FIG. 4, the roll of fabric 42 may be placed on a lower spindle 46 and the roll of conductive foil 44 (e.g., rolled annealed copper, etc.) may be placed on an upper spindle 48. The fabric 42 and the conductive foil 44 may both be fed through two compression rollers 50a, b. Also, the adhesive 14 flowed into the fabric 44 and/or the conductive foil 44 may be preheated prior to compression to promote adhesion (step 108) of the conductive foil 44 onto the adhesive 14. Additionally or alternatively, the compression rollers 50a, b may be heated to simultaneously heat and compress the foil 44 onto the adhesive 14. Since the adhesive 14 may be effectively formulated to bond well to the conductive foil 44, the conductive foil 44 is not likely to delaminate from the adhesive 14 when the flexible circuit 10 is cyclically bent or twisted or subjected to thermal stresses.

After the conductive foil 44 has been bonded (step 108) onto the adhesive 14, the resulting fabric 52 (see FIG. 4) or laminate may be wrapped around a third tube 54 for ease of transportation through the fabricating plant. As used herein, the “fabric 52” or laminate refers to fabric with adhesive flowed between the fabric's interstices and cured and with conductive foil bonded to the adhesive on one or both sides of the fabric 42. Alternatively, the adhesive 14 may be fully cured (step 110) immediately after laminating (step 108) the conductive foil 44 onto the adhesive 14 before the resulting fabric 52 is rolled onto the third tube 54.

As shown in FIG. 5, the resulting fabric 52 (see FIG. 4) may be cut into square sheets 56 or other shapes to fit a conductive pattern 16 (see FIG. 1). To form (step 104) the conductive pattern 16 via the subtractive process, a mask 58 is laid (step 112) down on the conductive foil 44 in the configuration of the conductive pattern 16. The sheet 56 with the mask 58 is submersed (step 114) in a suitable etching solution which dissolves the conductive foil 44 as a negative of the conductive pattern's configuration. The conductive foil 44 is removed from the adhesive 14 only where exposed to the etching solution and not covered by the mask 58. The mask 58 may be a photo-resist layer. After the etching solution has dissolved the conductive foil 44, the conductive pattern 16 may be exposed by removing (step 116) the mask 58. After the conductive pattern 16 has been formed (step 104) on the sheet 56 of the fabric 52, the resulting fabric 60 (see FIG. 5) may be die cut into the overall shape of the flexible circuit 10 as shown by the dashed lines 62 in FIG. 5. In the die cutting process, the die must be accurately located with respect to the resulting fabric 60. Otherwise, the die knives will cut through the conductive pads and the conductive traces damaging the flexible circuit. Fortunately, the resulting fabric 60 does not expand or contract excessively due to the reinforced characteristic from the base layer. As such, die cutting the resulting fabric 60 into the overall shape of the flexible circuit 10 does not excessive damage products. As used herein, the “fabric 60” refers to fabric with adhesive flowed between its interstices and with a conductive pattern formed on the adhesive of at least one side of the fabric.

Alternatively, the conductive pattern may also be formed on the adhesive via the additive process. In particular, adhesive may be flowed into the interstices of the fabric. The adhesive may be fully cured. Thereafter, the conductive pattern may be deposited directly onto the fully cured adhesive. By way of example and not limitation, the additive process may be sputtering process, an electroless process followed by electro plating, or a direct electro plate process.

Conductive patterns 16 may also be formed on the adhesive 14 of both sides of the fabric 42 by laminating a conductive foil 44 onto the adhesive 14 of the first and second sides of the fabric 12 and fully curing the adhesive 14. Thereafter, the conductive pattern 16 may be formed via the print and etch process discussed above. Additionally, conductive patterns 16 may be formed on the adhesive of both sides of the fabric 42 via the additive process.

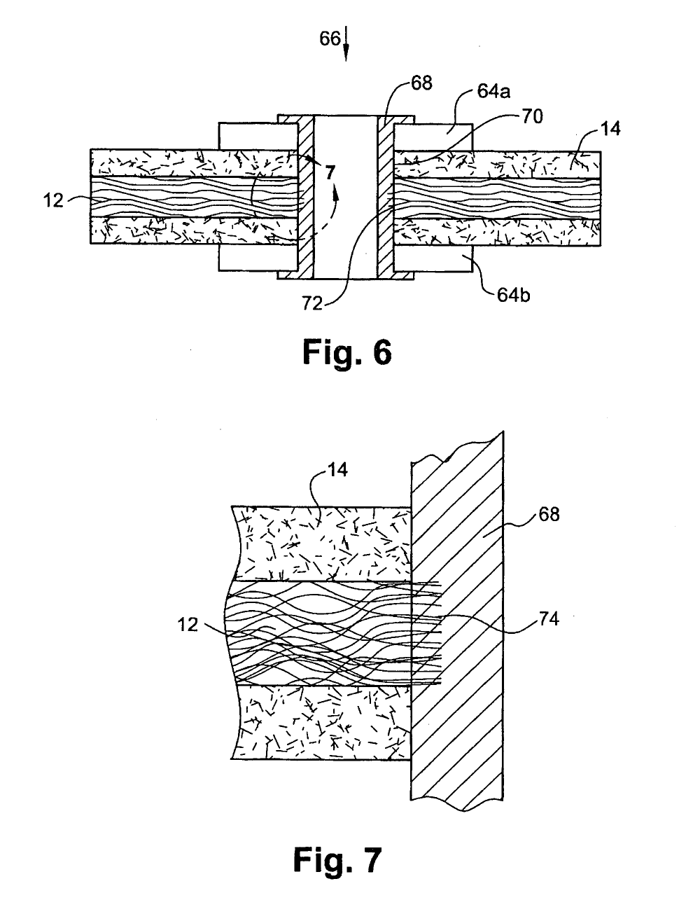

Additionally, the conductive pattern 16 on the adhesive 14 of the first side of the fabric 42 may be placed in electrical communication with the conductive pattern 16 on the adhesive 14 of the second side of the fabric 42, as shown in FIG. 6. In particular, the fabric's interstices may be flowed with flexible adhesive 14. The flexible adhesive 14 may be cured. A conductive plane 44 may be bonded to the adhesive 14 on both sides of the fabric 12. A through hole 66 may be drilled through the conductive planes 44 bonded to the adhesive 14 on both sides of the fabric 12. The through hole 66 may have frayed ends 74 of the fabric 12 exposed at its inner surface 72 facilitating bonding of the electroless deposit in the through hole. Conductive material or layer 68 may be electroplated in the through hole 66 on the through hole's inner surfaces 70, 72. Advantageously, the conductive material 68 flows between the frayed ends 74 of the fabric 12. This prevents the plating conductive material 68 from delaminating from the fabric 12 when the flexible circuit is bent, flexed, twisted, and/or subjected to thermal stresses. The conductive patterns 16 may be printed and etched into the conductive planes 44 on both sides of the fabric 12 with conductive pads 64a, b vertically aligned to each other and a central axis of the through hole 66. Beneficially, the plated through hole resists failure due z axis expansion.

The conductive material or layer 68 and the conductive pads 64a, b are shown in FIG. 6 as two separate materials. However, typically, the conductive material or layer 68 coalesce such that the conductive material or layer 68 and the conductive pads 64a, b form a unitary structure, although two separate structures are contemplated as shown in FIG. 6. The structure shown in FIG. 6 was shown to illustrate that the conductive material or layer 68 which was electroplated in the through hole 66 flows between the frayed ends 74 of the fabric. FIG. 6 is provided herein as by way of example and not limitation.

The flexible circuit 10 may be covered with an electrically insulating material typically referred to as a solder mask or cover layer. More particularly, the conductive pattern 16 may be covered with the cover layer. Also, selective pads and selective portions of the conductive pattern may be exposed for electrical access. The cover layer may be applied in liquid form or film form. Additionally, the cover layer may be the fabric 42 or a fabric with fully cured adhesive flowed between the interstices of the fabric, as shown in FIG. 10. Also, as shown in FIG. 10, it is contemplated that flexible circuits 10 may be stacked upon each other.

The fabric 12 may be a woven fabric. The fabric may be non-electrically conductive. The fabric 12 may have a low dielectric constant. The fabric 12 may also be reinforced in that the fabric is stable throughout the process discussed above. In particular, reinforced fabric 12 does not retain any significant amount of residual stresses due to the thermal stresses, compressive stresses and other like stresses imposed on the fabric 12 during the process discussed above. Also, the fabric 12 does not excessively shrink or expand due to the fabricating process discussed herein providing minimal expansion and contraction of the flexible circuit 10. Hence, the number of flexible circuits 10 rejected due to excessive contraction or expansion of the fabric 12 is minimized. By way of example and not limitation, the fabric 12 may be liquid crystal polymer (LCP) fabric, LCP, LCP mesh, quartz, fiberglass, fiberglass mesh, polymer, polyester, polyester mesh, Teflon, aramid fiber or the like. Typically, the fabric 12 may be about 0.01 millimeters to about 0.1 millimeters thick. Typically, the fabric's yarn may have a thickness of about 0.0002 inches to about 0.0007 inches. For fiberglass type 101, the fabric's thickness may be about 0.001 inches with a thread count of about 75×75 per inch. For fiberglass type 104, the fabric's thickness may be about 0.0012 inches with a thread count of about 60×52 per inch. For fiberglass type 106, the fabric's thickness may be about 0.0015 inches with a thread count of about 56×56 per inch. For fiberglass type 1080, the fabric's thickness may be about 0.0025 inches with a thread count of about 60×47 per inch.

More generally, the fabric may be a base layer. The base layer may be flexible and porous. For example, the base layer may be a porous non-woven fabric. The non-woven fabric may be sufficiently porous to permit adhesive to flow through pores of the non-woven fabric. Alternatively, the base layer may be a film with a plurality of apertures formed through the film so as to make the film porous. The plurality of apertures permits adhesive to flow through the film. The apertures may have a circular configuration about 0.020 inches to about 0.025 inches in diameter. The apertures may be formed in the film in a 0.050 inch grid pattern.

The adhesive 14 may be made by polymerizing monomers. The adhesive 14 may be flexible when fully cured. The adhesive 14 may have a low dielectric constant. The adhesive 14 may be cureable to a “B” stage. At the “B” stage, the adhesive 14 is not fully cured but dry to the touch. The adhesive 14 may be formulated to form a stronger bond to the conductive foil 44 (e.g., conductive pattern 16) than to the fabric 12 such that the conductive pattern 16 does not delaminate from the adhesive 14 as the flexible circuit 10 is flexed and bent or subjected to thermal stresses. In particular, the bond strength of the adhesive 14 to the conductive foil 44 may be greater than the bond strength of the adhesive 14 to the fabric 12. Accordingly, the conductive pattern 16 is unlikely to delaminate from the adhesive 14. The adhesive 14 may also remain attached to the fabric 12 due to the bonding between the adhesive 14 and the fabric 12 but more so because the adhesive 14 is flowed into the interstices of the fabric 12 then cured. By way of example and not limitation, the adhesive may be polyurethane adhesive, liquid crystal polymer based adhesive, or a high temperature adhesive such as a polyamide based adhesive, polyimide adhesive and butyl al phenolic based adhesive.

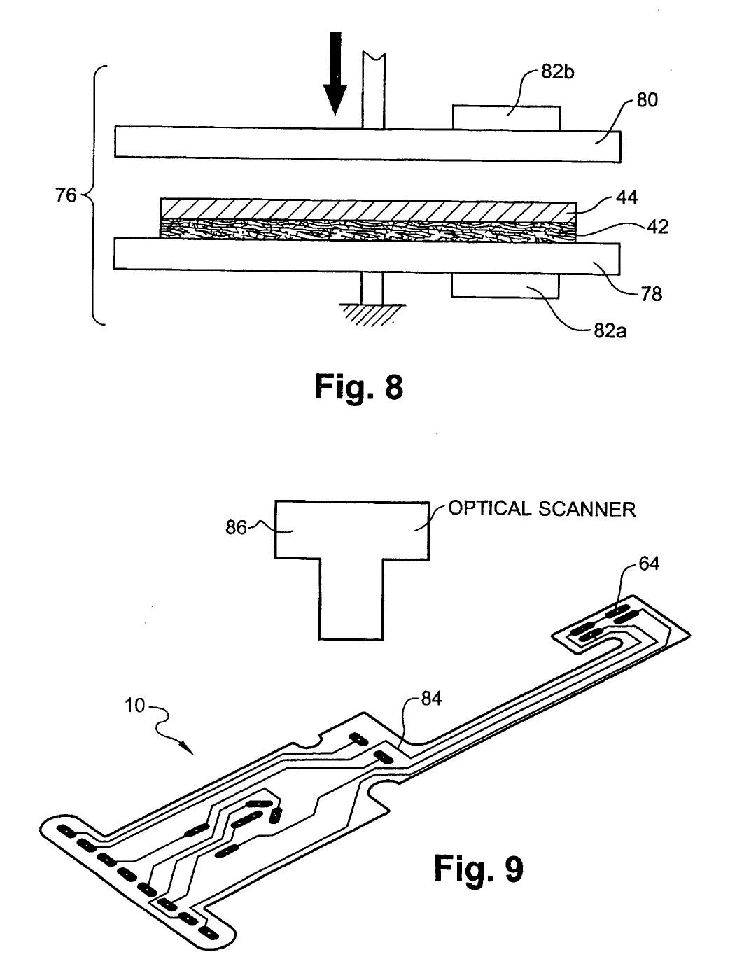

In another aspect, instead of compressing the conductive foil 44 onto the adhesive 14, as shown in FIG. 4, the conductive foil 44 may be heat pressed onto adhesive 14 on one side of the fabric 42. For example, as shown in FIG. 8, a platen press 76 may press a sheet of conductive foil 44 onto a sheet of fabric 42. In particular, the fabric 42 may be cut into a square sized sheet and disposed on a lower platen 78 of the platen press 76. Also, the conductive foil 44 may be provided as a square sized sheet and disposed on top of the fabric 42 under an upper platen 80. The upper and lower platens 78, 80 may each be connected to a heater 82a, b. To bond the conductive foil 44 to the adhesive 14 flowed into the fabric 42, the upper and lower platens 78, 80 may be heated via the heaters 82a, b. Once the platens's temperature has been sufficiently raised, the upper platen 80 may apply pressure onto the conductive foil 44 to adhere the conductive foil 44 onto the adhesive 14 flowed into the fabric 12. With the simultaneous application of pressure and heat, the adhesive 14 may be fully cured and the copper foil 44 may be bonded to the adhesive 14 of the fabric 42.

In another aspect, the conductive pattern 16 may be screen printed onto the adhesive 14. For example, a flexible conductive ink composition may be deposited onto the surface of the adhesive 14 via screen printing techniques. If the conductive ink composition is screen printed onto the adhesive 14, then preferably, the conductive ink composition is electro deposited copper.

In another aspect, the fabric 12 may be pretreated to promote bonding between the adhesive 14 and the fabric 12. In particular, the fabric 12 may subjected to a silane treatment.

In another aspect, the adhesive may be flowed into the fabric's interstices by placing a sheet of adhesive onto one or both sides of the fabric 12. The sheet of adhesive may be heated and compressed onto the fabric such that the adhesive is melted and flows between the fabric's interstices. After the adhesive has flowed into the fabric's interstices, the adhesive may be cured to the “B” stage or fully cured. As used herein, flow refers to any process for disposing adhesive 14 between the interstices of the fabric 12 or the pores of the base layer.

In another aspect, the base layer may be fabricated from liquid crystal polymer (LCP) threads or polyester threads wherein liquid crystal polymers and polyesters have desirable electrical characteristics. For example, liquid crystal polymers and polyesters permit high speed electrical signals to be sent through a conductive pattern attached thereto. The threads may be woven or non-woven to form the base layer. Flexible adhesive based from the same material as the base layer (i.e., LCP) may be flowed through pores or interstices of the base layer. For example, liquid crystal polymer based adhesives may be flowed into the pores or interstices of the liquid crystal polymer base layer. Likewise, polyester based adhesives may be flowed into the pores or interstices of the polyester base layer. Thereafter, a conductive pattern may be formed on the adhesive. The flexible circuit of the present invention permits a base layer having desireable characteristics to be flowed with adhesive from the same type of material as the base layer to provide for a base layer with predictable and desireable electrical characteristics.

In another aspect of the present invention, flowing adhesive through pores of a base layer permits fabrication of a base layer having a first electrical characteristic to be flowed with adhesive also having the first electrical characteristic. For example, a porous base layer having a low dielectric constant may have flexible adhesive also having a low dielectric constant to be flowed into the pores of the base layer or the interstices of the fabric then cured. The conductive pattern may then be formed on the adhesive having a low dielectric constant. Accordingly, the combination of base layer and adhesive material is not limited to the adhesion strength between the adhesive and the base layer. Rather, any type of flexible adhesive may be flowed into the pores of the base layer.

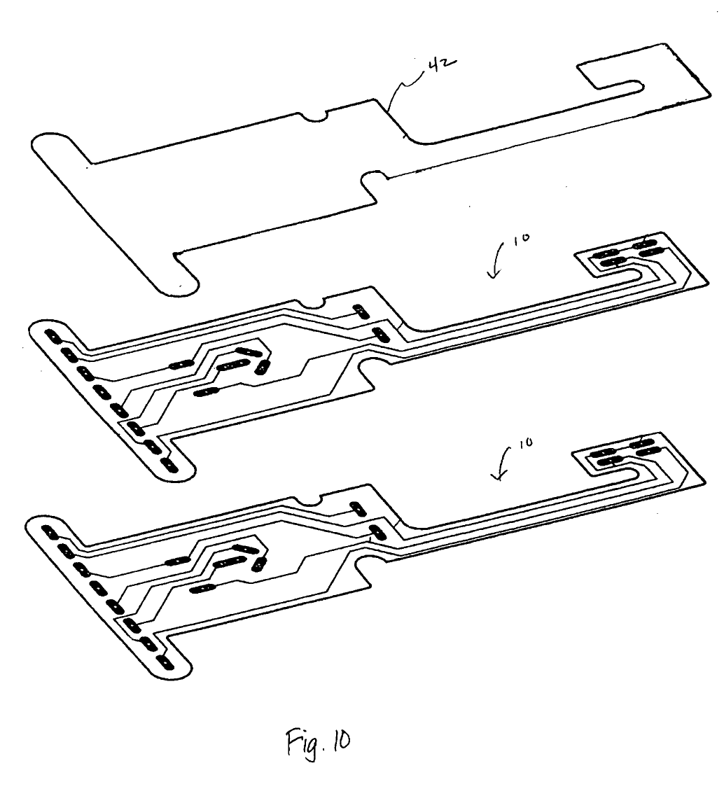

In another aspect, the flexible circuit 10 fabricated via the method discussed herein may be optically scanned for defects, as shown in FIG. 9. For example, the overall size of the flexible circuit 10 and the positions of the conductive pads 64 and conductive lines 84 may be optically checked via an optical scanner 86 to determine whether the flexible circuit 10 is within design tolerances. If the flexible circuit 10 is not within design tolerances, then the flexible circuit 10 is rejected. The flexible circuit of the present invention is dimensionally stable due to the reinforced nature of the flexible circuit of the present invention. Thus, the flexible circuit of the present invention may be optically scanned for defects. In contrast, as discussed in the background, prior art flexible circuits are dimensionally unstable due to the non reinforced nature of the prior art flexible circuits. Thus, prior art flexible circuits may not be optical scanned for defects.

The above description is given by way of example, and not limitation. Given the above disclosure, one skilled in the art could devise variations that are within the scope and spirit of the invention disclosed herein, including various ways of forming the conductive pattern 16. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A flexible printed circuit comprising:
a) a base layer being flexible and porous, the base layer having a plurality of pores;
b) a flexible adhesive flowed into the pores of the base layer for resisting delamination between the base layer and the flexible adhesive; and
c) a conductive pattern bonded to the flexible adhesive.

2. The flexible printed circuit of claim 1 comprising a plurality of base layers, flexible adhesives and conductive patterns stacked upon each other.

3. The circuit of claim 1 wherein the adhesive is a flexible polymerized monomer.

4. The circuit of claim 1 wherein the adhesive is formulatable to bond to the conductive pattern for resisting delamination of the conductive pattern from the adhesive, the bond between the adhesive and the conductive pattern being greater than the bond between the adhesive and the fabric for resisting delamination of the adhesive from the fabric when the flexible printed circuit is cyclically bent and subjected to thermal stresses.

5. The circuit of claim 1 wherein the base layer is a woven fabric and the pores are interstices of the fabric, and the flexible adhesive is flowed into the interstices of the woven fabric.

6. The circuit of claim 1 wherein the base layer is a porous non-woven fabric, and the flexible adhesive is flowed into the pores of the non-woven fabric.

7. The circuit of claim 1 wherein the base layer is a film with a plurality of apertures, and the flexible adhesive is flowed into the apertures.

8. The circuit of claim 1 wherein the fabric is fiberglass, fiberglass mesh, polymer, polyester, polyester mesh, LCP, LCP mesh, Teflon, quartz, or aramid fiber.

9. The circuit of claim 1 wherein the adhesive is a polyurethane adhesive, a liquid crystal polymer based adhesive, a high temperature adhesive, a polyamide based adhesive, a polyimide adhesive, or a butaryl phenolic based adhesive.

10. The circuit of claim 1 wherein the conductive pattern is a rolled annealed copper or an electro deposited copper.

11. A method of fabricating a flexible printed circuit, the method comprising the steps of:
a) providing a base layer being flexible and porous;
b) flowing flexible adhesive into pores of the base layer;
c) forming a conductive pattern on the adhesive.

12. The method of claim 11 wherein the forming the conductive pattern step comprises the steps of:
i) curing the adhesive to a “B” stage;
ii) bonding a conductive plane to the adhesive;
iii) fully curing the adhesive;
iv) masking the conductive plane in a configuration of the conductive pattern;
v) submersing the base layer in etching solution; and
vi) removing the mask.

13. The method of claim 11 wherein the forming the conductive pattern step comprises the steps of:
i) fully curing the adhesive; and
ii) depositing the conductive pattern directly onto the fully cured adhesive.

14. The method of claim 13 wherein the depositing step is accomplished via a sputtering process, an electroless process followed by electro plating, or a direct electro plate process.

15. The method of claim 11 wherein the flowing step comprises the step of submersing the base layer in a bath of melted flexible adhesive.

16. The method of claim 11 wherein the flowing step comprises the steps of:
i) providing adhesive in a solid state;
ii) positioning the adhesive adjacent to the base layer;
ii) melting the adhesive; and
iii) compressing the adhesive in between the pores of the base layer.

17. The method of 11 wherein the forming step comprises the steps of:
i) forming a first conductive pattern on a first side of the base layer; and
ii) forming a second conductive pattern on a second side of the base layer.

18. The method of claim 17 further comprising the steps of:
e) forming a through hole from the first side to the second side of the base layer to provide an electrical communications pathway to connect the first conductive pattern to the second conductive pattern;
f) exposing frayed ends of the base layer into the through hole;
g) flowing a plating conductive material between the frayed ends for resisting delamination between the plating material and the base layer; and
h) plating the through hole with a conductive material such that the first conductive pattern is in electrical communication with the second conductive pattern.
